(19) United States
(12) Patent Application Publication
(10) Pub. No.: US 2006/0124589 A1
(43) Pub. Date: Jun. 15, 2006

(54) Apparatus and method for removing photoresist in a semiconductor device

(76) Inventor: Dae-Gun Lee, Icheon-city (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/303,466

(22) Filed: Dec. 15, 2005

(30) Foreign Application Priority Data
Dec. 15, 2004 (KR) 10-2004-0106146

(51) Int. Cl. C23F 1/00; H01L 21/302; B44C 1/22; C03C 25/68

(52) U.S. Cl. 216/67; 156/345.48; 438/706; 438/710

(57) ABSTRACT

A photoresist in a semiconductor device with copper wiring is effectively removed at a low temperature of 25° C. using a photoresist removing apparatus that includes a vacuum chamber, a plasma generator located in the upper side of the chamber, and a wafer chuck that is insulated at all but a wafer-contacting surface, that is applied with an RF bias power, and that is located in the lower side of the chamber.

### CROSS-REFERENCE TO RELATED APPLICATION

This application claims priority to and the benefit of Korean Patent Application No. 10-2004-0106146, filed in the Korean Intellectual Property Office on Dec. 15, 2004, the entire contents of which are incorporated herein by reference.

### BACKGROUND OF THE INVENTION

(a) Field of the Invention

The present invention relates to an apparatus and a method for removing a photoresist from a (semiconductor) wafer. More particularly, the present invention relates to an apparatus and a method for removing a photoresist in a semiconductor device having copper wiring.

(b) Description of the Related Art

Recently, as semiconductor integrated circuits have become more highly integrated and their operation speed has increased, a metal line in a semiconductor device has become narrower and multi-layered. In addition, copper wiring and low dielectric constant materials have been proposed for minimizing an RC signal delay. In addition, there is a difficulty in patterning the wiring as design rules have shrunk. Thus, a damascene process has been developed to skip a metal etching step and an insulator gap-filling step in a metallization process.

Such a damascene process may be categorized as single damascene and dual damascene processes, and a conventional method of metallization by a dual damascene process will hereinafter be described as an example of a general damascene process.

An etch stop layer, an intermetal insulating layer, and an anti-reflection layer are sequentially formed on a lower metal layer, and then a via mask is formed on the anti-reflection layer. A via hole is formed by selectively etching the anti-reflection layer and the intermetal insulating layer using the via mask and then ashing the mask.

After filling the via hole with a sacrificial layer, the sacrificial layer is recessed to a predetermined depth. Then, after coating an anti-reflection layer, a trench mask is formed on the anti-reflection layer, and a trench is formed by a dry etching process using the trench mask.

Subsequently, the trench mask and the sacrificial layer remaining in the via hole are removed by an ashing process. In addition, the etch stop layer exposed in the bottom of the via hole is removed so as to complete a dual damascene pattern including a via hole and a trench. A metallization process is then completed by subsequently forming a barrier metal layer in the damascene pattern, filling the damascene pattern with a conductive material such as copper, and polishing the conductive material.

In such a dual damascene process, the via mask, the trench mask, and the sacrificial layer in a via hole are generally composed of a photoresist. For an ashing process to remove the photoresist, a conventional photoresist removing apparatus uses an oxygen plasma by a down-streaming method. The photoresist layer is typically reacted with the plasma at a high temperature of about 100-250° C.

In a semiconductor device with aluminum metallization, the high process temperature of the ashing process has little effect on device characteristics. However, in a semiconductor device with copper metallization, the high process temperature enables oxygen atoms to penetrate into the copper layer and react with copper so as to deteriorate characteristics of the copper. Consequently, the resistance of the copper layer increases, so characteristics of the device generally deteriorate.

The above information disclosed in this Background section is only for enhancement of understanding of the background of the invention, and therefore, it may contain information that does not form information or prior art that may be already known in this or any other country to a person of ordinary skill in the art.

### SUMMARY OF THE INVENTION

The present invention has been made in an effort to provide an apparatus and a method for removing a photoresist in a semiconductor device having an advantage of effective removal of a photoresist in a semiconductor device with copper wiring.

An exemplary apparatus for removing a photoresist from a wafer (e.g., having thereon a semiconductor device with copper wiring) according to an embodiment of the present invention includes a vacuum chamber, a plasma generator located in the upper side of the chamber, and a wafer chuck that is insulated at all but a wafer-contacting surface, that may apply an RF bias power (or have the RF bias power applied to it), and that is located in the lower side of the chamber. A photoresist on the wafer therein is removed at a temperature of 20-50° C., and preferably at about 25° C. In addition, an upper surface of the wafer chuck may be flat (e.g., without protrusions and/or depressions) in order to reduce or prevent damage due to plasma. Here, the reason of the low temperature of 20-50° C. for removing the photoresist is because oxygen penetration into the copper layer is effectively suppressed at such a low temperature.

A method for removing a photoresist from a semiconductor device with copper wiring using the apparatus generally includes loading a wafer (generally comprising the semiconductor device with copper wiring) on the wafer chuck in the chamber, stabilizing a process condition such as gas flow, chamber pressure, temperature, etc., to a setting point, generating plasma at a temperature of 20-50° C. by supplying a source power, and removing the photoresist (e.g., by exposing the photoresist-coated wafer to the plasma).

The process condition(s) to be stabilized may vary depending on whether the photoresist is used for etching or defining a via hole, etching a trench, or filling a via hole as a sacrificial layer.

When removing a photoresist used to etch or define a via hole, O₂ may be flowed into the chamber at a rate of from 2000 to 3000 sccm and N₂ may be flowed into the chamber at a rate of from 200 to 300 sccm, a process time may be from 50 to 90 sec, a chamber pressure may be from 0.7 to 1.3 Torr, a chamber temperature may be from 20 to 50° C., a source power may be from 2000 to 3000 MW, and an RF bias power may be from 100 to 200 W. In one implementation, the O₂ may be flowed at a rate of about 2500 sccm and the N₂ at a rate of about 250 sccm, the process time may be about 70 sec, the pressure of the process chamber may be maintained at a level of about 1.0 Torr, the temperature of the process chamber may be maintained at about 25° C., the source power may be about 2500 MW, and the RF bias power may be about 150 W.

When removing a photoresist used to etch or define a trench, O₂ may be flowed into the chamber at a rate of from 2000 to 3000 sccm and N₂ at a rate of from 200 to 300 sccm, the process time may be from 90 to 150 sec, the chamber pressure may be from 1.3 to 1.9 Torr, the chamber temperature may be from 20 to 50° C., the source power may be from 2000 to 3000 MW, and the RF bias power may be from 150 to 250 W. In one implementation, the O₂ may be flowed into the chamber at a rate of about 2500 sccm and the N₂ at a rate of about 250 sccm, the process time may be about 120 sec, the pressure of the process chamber may be maintained at about 1.6 Torr, the temperature of the process chamber may be about 25° C., the source power may be maintained at about 2500 MW, and the RF bias power may be maintained at about 200 W.

When recessing a photoresist used as a sacrificial layer in a via hole, O₂ may be flowed into the chamber at a rate of from 300 to 1300 sccm and N₂ may be flowed into the chamber at a rate of from 30 to 130 sccm, the process time may be from 3 to 10 sec, the chamber pressure may be from 0.2 to 0.8 Torr, the chamber temperature may be from 20 to 50° C., the source power may be about 0 W, and the RF bias power may be from 60 to 160 W. In one implementation, the O₂ may be flowed at a rate of about 800 sccm and N₂ at a rate of about 80 sccm, the process time may be about 5 sec, the pressure of the process chamber may be maintained at a level of about 0.5 Torr, the temperature of the process chamber may be maintained at about 25° C., and the RF bias power may be about 110 W.

### BRIEF DESCRIPTION OF THE DRAWINGS

FIG. 1 is a schematic diagram showing a photoresist removing apparatus according to an exemplary embodiment of the present invention.

FIG. 2 is a process flowchart showing a method of removing a photoresist, for example using the apparatus of FIG. 1.

FIG. 3 is a top view picture of via holes after a photoresist is removed therefrom by a process condition (or set of process conditions) according to an exemplary embodiment of the present invention.

FIG. 4 is a top view picture of trenches after a photoresist is removed therefrom by a process condition (or set of process conditions) according to an exemplary embodiment of the present invention.

FIG. 5 is a picture of via holes in which a photoresist used for a sacrificial layer is recessed by a process condition (or set of process conditions) according to an exemplary embodiment of the present invention.

FIG. 6 shows experimental data of a concentration of oxygen in a copper layer when a photoresist is removed at a low temperature in the range of 20-50° C. using the present method of removing photoresist and the photoresist removing apparatus of FIG. 1.

FIG. 7 shows experimental data of a concentration of oxygen in a copper layer when a photoresist is removed at a high temperature of 150° C. using a conventional photoresist removing apparatus and method.

FIG. 8 shows experimental data of a concentration of oxygen in a copper layer when a photoresist is removed at a high temperature of 260° C. by using a conventional photoresist removing apparatus and method.

### DETAILED DESCRIPTION OF THE EMBODIMENTS

An exemplary embodiment of the present invention will hereinafter be described in detail with reference to the accompanying drawings.

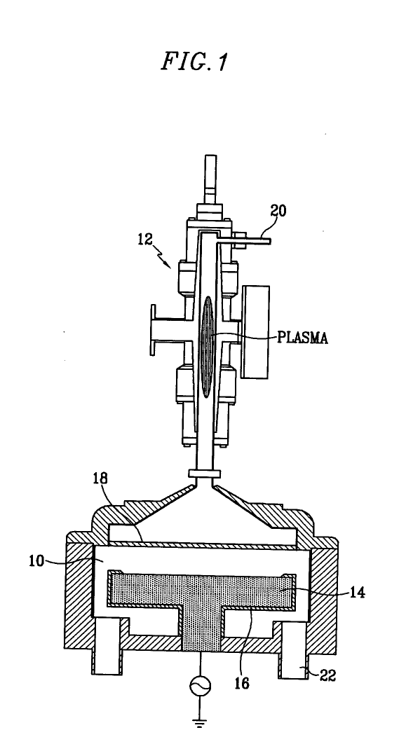

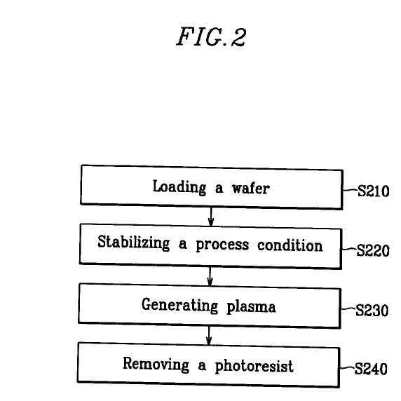

FIG. 1 is a schematic diagram showing a photoresist removing apparatus according to an exemplary embodiment of the present invention.

The photoresist removing apparatus according to an exemplary embodiment includes a process chamber 10 that is capable of maintaining a high vacuum in its interior. A plasma generator 12 is located in an upper side or portion of the chamber 10, and a wafer chuck 14 is located in a lower side or portion of the chamber 10.

The wafer chuck 14 applies (or has applied thereto) an RF bias power to maintain an ashing rate of the photoresist within a predetermined level or range, and an upper surface of the wafer chuck 14 is flat (e.g., without protrusions and depressions) in order to prevent damage due to uneven or non-uniform plasma.

In addition, the wafer chuck 14 is insulated over the entire exposed surface (excluding a wafer-contacting surface) by an insulator 16, and the reason thereof is given as follows. A distance between a wafer chuck and a sidewall of the chamber is usually shorter than a distance between a wafer chuck and the top of the chamber. In this case, plasma may be generated at or near the side wall of the chamber when an RF bias power is applied to the wafer chuck. Therefore, the wafer chuck 14 is insulated by the insulator 16 so as to reduce, minimize, or not generate such plasma at the side wall of the chamber.

Reference numeral 18 of FIG.1 denotes a quartz plate, reference numeral 20 denotes an inflow pipe for one or more process gases, and reference numeral 22 denotes an exhaust pipe (e.g., operably connected to a vacuum pump), which are not explained hereinabove.

By the photoresist removing apparatus as described above, a photoresist may be removed at a low temperature of 20-50° C., and preferably about 25° C., and a chiller (not shown) may be operably connected to the apparatus (particularly the chamber) and used to maintain the low chamber temperature.

Hereinafter, a method for removing a photoresist using the photoresist removing apparatus will be described in detail.

A method for removing a photoresist according to an exemplary embodiment of the present invention includes loading a wafer on the wafer chuck 14 in the chamber 10 at step S210; stabilizing one or more process conditions, such as gas flow, chamber pressure, temperature, etc., to a setting point at step S220; generating a plasma at a temperature of 20-50° C. by supplying a source power at step S230; and removing the photoresist at step 240.

At the step S220, the process conditions may be set differently depending on the particular case (for example, whether the photoresist to be removed has been used to etch or define a via hole or a trench, or whether the photoresist fills a via hole as a sacrificial layer and is to be recessed).

When removing a photoresist that may have been used in etching or defining a via hole, a process gas comprising O₂ and N₂ may have respective flow rates of 2000-3000 sccm and 200-300 sccm, a process time may be 50-90 sec, a pressure of the process chamber may be maintained at a level of 0.7-1.3 Torr, a temperature of the process chamber may be maintained at 20-50° C., a source power may be maintained at 2000-3000 MW, and/or an RF bias power may be maintained at 100-200 W. More specifically, O₂ may be flowed at about 2500 sccm and N₂ at about 250 sccm, the process time may be about 70 sec, the process chamber pressure may be about 1.0 Torr, the process chamber temperature may be about 25° C., the source power may be about 2500 MW, and the RF bias power may be about 150 W.

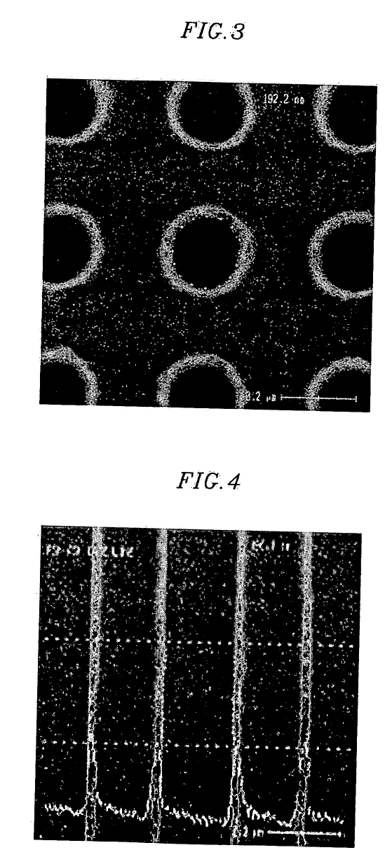

FIG. 3 shows that the photoresist used in etching a via hole is effectively removed by the process conditions as described above.

When removing a photoresist that may have been used in etching or defining a trench, the process gas may comprise O₂ at a flow rate of 2000-3000 sccm and N₂ at a flow rate of 200-300 sccm, a process time of from 90 to 150 sec, chamber pressure of from 1.3 to 1.9 Torr, chamber temperature of from 20 to 50° C., a source power of from 2000 to 3000 MW, and an RF bias power of from 150 to 250 W. In more detail, the O₂ may be flowed at a rate of about 2500 sccm and the N₂ at a rate of about 250 sccm, the process time may be about 120 sec, the pressure of the process chamber may be maintained at a level of about 1.6 Torr, the temperature of the process chamber may be maintained at about 25° C., the source power may be about 2500 MW, and the RF bias power may be about 200 W.

FIG. 4 shows that the photoresist used in etching (or defining) a trench is effectively removed by the process conditions as above. In addition, when recessing a photoresist that may be or comprise a sacrificial layer in a via hole, the process gas may comprise O₂ at a flow rate of 300-1300 sccm and N₂ at a flow rate of 30-130 sccm, the process time may be from 3 to 10 sec, the chamber pressure may be 0.2 to 0.8 Torr, the chamber temperature may be 20 to 50° C., the source power may be about 0 W, and the RF bias power may be from 60 to 160 W. In more detail, the process gas may comprise O₂ at a flow rate of about 800 sccm and N₂ at a flow rate of about 80 sccm, the process time may be about 5 sec, the pressure of the process chamber may be maintained at a level of about 0.5 Torr, the temperature of the process chamber may be maintained at about 25° C., and the RF bias power may be about 110 W.

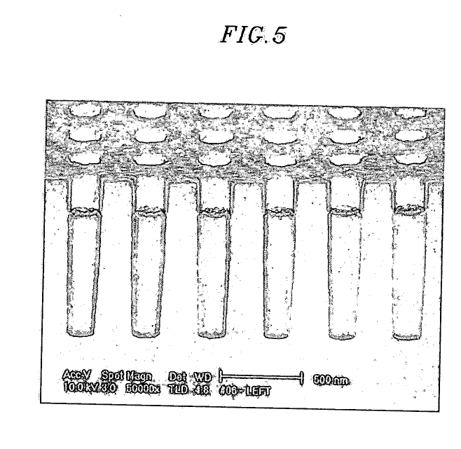

FIG. 5 shows that a photoresist that may be used for or that may comprise a sacrificial layer in a via hole is effectively recessed by the process conditions as above.

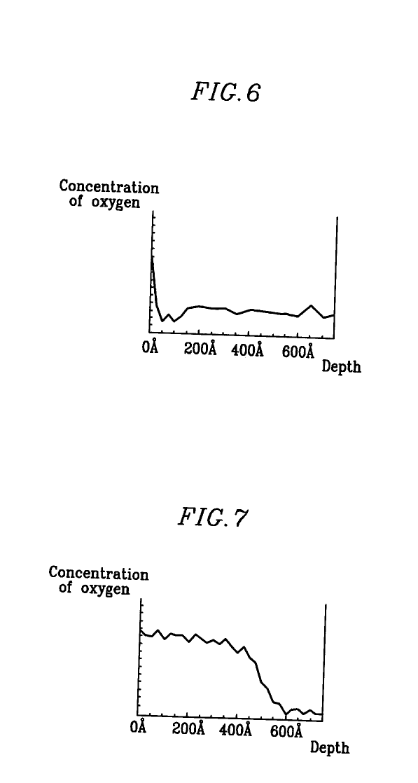

FIG. 6 is a graph of experimental data showing a concentration of oxygen in a copper layer when a photoresist is removed at a low temperature of 20-50° C. using the present photoresist removing apparatus and method. Referring to the data, the concentration of oxygen at a depth of over 50 Å below the surface of the copper layer is very low.

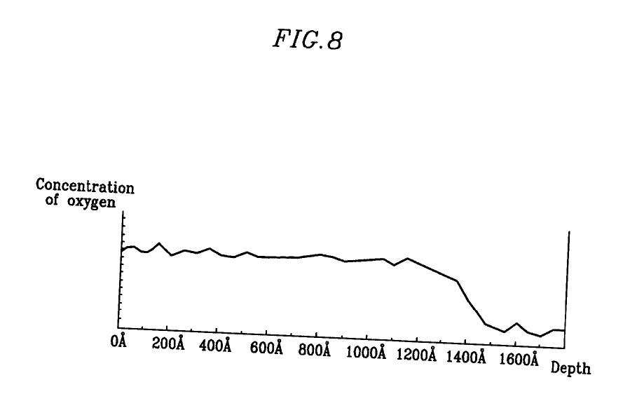

On the other hand, referring to experimental data of FIG. 7 and FIG. 8, when a photoresist is removed using a conventional photoresist removing apparatus and method at a high temperature of 150° C. as shown in FIG. 7 or of 260° C. as shown in FIG. 8, the concentration of oxygen below the surface of the copper layer is much higher compared with the data of FIG. 6.

As described above, according to an exemplary embodiment of the present invention, a photoresist is effectively removed at a low temperature of 25□ by using the photoresist removing apparatus. In such a low temperature process, oxygen penetration into a copper layer is effectively decreased, and thus a change of resistance of the copper layer is minimized.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An apparatus for removing a photoresist from a wafer, comprising:
a vacuum chamber;
a plasma generator in an upper side of the vacuum chamber; and
a wafer chuck at a lower side of the vacuum chamber and receiving an RF bias power, the wafer chuck being insulated on its entire surface excluding a surface in contact with the wafer.

2. The apparatus of claim 1, wherein the chamber is configured to have a temperature of 20-50° C. during removal of a photoresist from the wafer.

3. The apparatus of claim 2, wherein the temperature is about 25° C.

4. The apparatus of claim 1, wherein an upper surface of the wafer chuck is flat.

5. The apparatus of claim 1, wherein the wafer comprises a semiconductor device having copper wiring.

6. A method for removing a photoresist from a wafer, comprising:
loading the wafer on the wafer chuck in a vacuum chamber;
stabilizing a process condition for at least one of gas flow, chamber pressure, and temperature to a predetermined setting point;
generating plasma at a temperature of 20-50° C. by supplying a source power; and
removing the photoresist.

7. The method of claim 6, wherein the process condition depends on whether the photoresist was used to etch or define a via hole, etch or define a trench, or fill a via hole as a sacrificial layer.

8. The method of claim 6, wherein the photoresist was used to etch or define a via hole, and removing the photoresist comprises flowing a gas comprising O₂ at 2000-3000 sccm and N₂ at 200-300 sccm, for a time of from 50 to 90 sec, at a chamber pressure of from 0.7 to 1.3 Torr, a chamber temperature of from 20 to 50° C., a source power of from 2000 to 3000 MW, and an RF bias power of from 100 to 200 W.

9. The method of claim 8, wherein, in removing the photoresist, the O₂ is flowed at a rate of about 2500 sccm and the N₂ at a rate of about 250 sccm, the time is about 70 sec, the chamber pressure is maintained at a level of about 1.0 Torr, the chamber temperature is maintained at about 25° C., the source power is about 2500 MW, and the RF bias power is about 150 W.

10. The method of claim 6, wherein the photoresist was used to etch or define a trench, and removing the photoresist comprises flowing a gas comprising O₂ at a rate of from 2000 to 3000 sccm and N₂ at a rate of from 200 to 300 sccm, for a time of from 90 to 150 sec, at a chamber pressure of from 1.3 to 1.9 Torr, a temperature of from 20 to 50° C., a source power of from 2000 to 3000 MW, and an RF bias power of from 150 to 250 W.

11. The method of claim 9, wherein, in removing the photoresist, the O₂ is flowed at a rate of about 2500 sccm and the N₂ is flowed at a rate of about 250 sccm, the process time is about 120 sec, the pressure of the chamber is maintained at a level of about 1.6 Torr, the temperature of the chamber is maintained at about 25° C., the source power is maintained at about 2500 MW, and the RF bias power is maintained at about 200 W.

12. The method of claim 6, wherein the photoresist was used for a sacrificial layer in a via hole, and removing the photoresist comprises flowing a gas comprising O₂ at a rate of from 300 to 1300 sccm and N₂ at a rate of from 30 to 130 sccm, for a time of from 3 to 10 sec, at a chamber pressure of from 0.2 to 0.8 Torr, a chamber temperature of from 20 to 50° C., a source power of about 0 W, and an RF bias power of from 60 to 160 W.

13. The method of claim 12, wherein removing the photoresist comprises recessing the photoresist in the via hole, the O₂ is flowed at a rate of about 800 sccm and the N₂ is flowed at a rate of about 80 sccm, the time is about 5 sec, the pressure of the process chamber is maintained at about 0.5 Torr, the temperature of the process chamber is maintained at about 25° C., and the RF bias power is about 110 W.

14. A method of removing a photoresist, comprising:
supplying a source power to a photoresist removal apparatus comprising a chamber having a chamber temperature of 20-50° C. and at least one stable process condition selected from the group consisting of gas flow, chamber pressure, and temperature, sufficient to generate a plasma in the chamber; and
removing the photoresist from a wafer in the chamber.

15. The method of claim 14, wherein the process condition has a value depending on whether the photoresist defines a via hole, defines a trench, or fills a via hole.

16. The method of claim 14, wherein removing the photoresist comprises flowing a gas comprising O₂ at a rate of from 2000 to 3000 sccm and N₂ at a rate of from 200 to 300 sccm applying a source power of from 2000 to 3000 MW and an RF bias power of from 100 to 200 W.

17. The method of claim 16, wherein removing the photoresist is performed for a time of from 50 to 90 sec, at a chamber pressure of from 0.7 to 1.3 Torr.

18. The method of claim 16, wherein removing the photoresist is performed for a time of from 90 to 150 sec, at a chamber pressure of from 1.3 to 1.9 Torr.

19. The method of claim 14, wherein removing the photoresist comprises flowing a gas comprising O₂ and N₂, at a chamber pressure of from 0.2 to 0.8 Torr, and an RF bias power of from 60 to 160 W.

20. The method of claim 19, wherein the O₂ flow rate is from 300 to 1300 sccm, the N₂ flow rate is from 30 to 130 sccm, and removing the photoresist is performed for a time of from 3 to 10 sec and a source power of about 0 W.
